(19) United States
(12) Patent Application Publication
(10) Pub. No.: US 2012/0190552 A1
(43) Pub. Date: Jul. 26, 2012

(54) PRECOOLING DEVICE, SUPERCONDUCTING MAGNET AND MAGNETIC RESONANCE IMAGING APPARATUS

(76) Inventors: Zhi Chun Fang, Nanshan (CN); Lei Yang, Shenzhen (CN)

(21) Appl. No.: 13/355,964

(22) Filed: Jan. 23, 2012

(30) Foreign Application Priority Data
Jan. 26, 2011 (CN) 201120024427.7

(51) Int. Cl. F28F 7/00; F25D 31/00; H01F 6/04; G01R 33/28; F28F 1/10; H01F 6/00; F25B 19/00

(52) U.S. Cl. 505/162; 165/185; 165/181; 62/467; 505/163; 335/216; 62/51.1

(57) ABSTRACT

A precooling device for a thermal radiation shield of a superconducting magnet has a mechanical heat conductive member in contact with the thermal radiation shield of a superconducting magnet, for cooling the thermal radiation shield down to a second temperature before the second stage of precooling of the superconducting magnet, this second temperature being below the temperature of the thermal radiation shield after a first stage of precooling of the superconducting magnet. A superconducting magnet and magnetic resonance imaging equipment embody such a precooling device. The precooling device reduces the external radiation heat onto a cryogen vessel, thereby reducing the consumption of cryogen.

### BACKGROUND OF THE INVENTION

1. Field of the Invention

The present invention relates to precooling technology for superconducting magnets and, particularly, to a precooling device for a thermal radiation shield of a superconducting magnet, a superconducting magnet comprising the precooling device, and a magnetic resonance imaging apparatus embodying such a superconducting magnet.

2. Description of the Prior Art

Devices that are required to be cryogenically refrigerated, such as the superconducting coil of a superconducting magnet in magnetic resonance imaging (MRI) equipment, are generally placed in a cryogen vessel, the cryogen vessel is placed in an external vacuum chamber, and the space between the vacuum chamber and the cryogen vessel is evacuated, which provides effective heat insulation for the cryogen vessel. However, since the temperature difference between the exterior of the vacuum chamber and the interior of the cryogen vessel is relatively large, too much thermal radiation heat exists between the vacuum chamber and the cryogen vessel, so that in order to reduce the radiation heat between the vacuum chamber and the cryogen vessel, a thermal radiation shield is generally provided between the vacuum chamber and the cryogen vessel.

When precooling is carried out on the superconducting magnet, it is generally divided into two stages. At the first stage, the superconducting magnet is cooled down to a first temperature using a consumable cryogen (such as liquid nitrogen), and at the second stage, a certain quantity of a cryogen (such as liquid helium) is added into the superconducting magnet to cool the superconducting magnet down to a preset temperature, i.e. the operating temperature. The operating temperature is below the first temperature.

The above-mentioned precooling process is disclosed in British patent application with publication number GB2433581A, in which open-loop refrigeration is improved by changing to closed-loop refrigeration so as to reduce the consumption of cryogen.

However, in practical application, a further reduction of the cryogen consumption is always desirable.

### SUMMARY OF THE INVENTION

An object of the present invention is to provide a precooling device for a thermal radiation shield of a superconducting magnet, so as to reduce the radiation heat of the thermal radiation shield onto a cryogen vessel and to reduce the consumption of liquid helium. An object also is to provide a corresponding superconducting magnet and magnetic resonance imaging equipment.

This object is achieved in accordance with the invention by a precooling device for a thermal radiation shield of a superconducting magnet, wherein a superconducting coil of the superconducting magnet is provided in a cryogen vessel, the cryogen vessel is provided in an external vacuum chamber, and a thermal radiation shield is provided between the cryogen vessel and the external vacuum chamber. In accordance with the invention, a cooling source member and a mechanical heat conductive member, the cooling source member being used to provide cooling and the mechanical heat conductive member being in contact with the thermal radiation shield for actively cooling down the thermal radiation shield by utilizing the cooling provided by the cooling source member. For example, the thermal radiation shield is cooled down to a second temperature that is below the temperature of the thermal radiation shield after a first stage of precooling of the superconducting magnet.

According to an embodiment of the present application, the mechanical heat conductive member has a structure engaging with a cold head apron of the superconducting magnet and is fixed into the apron by the structure.

According to an embodiment of the present invention, the device is a heat exchanger, the mechanical heat conductive member includes a heat conductor and a heat exchange tube of the heat exchanger, and the heat conductor is in contact with the thermal radiation shield, and the heat exchange tube is connected to the cooling source and is in contact with the heat conductor.

According to another embodiment of the invention, the device is a mechanical refrigerator, and the mechanical heat conductive member is a heat conducting member of the mechanical refrigerator.

Furthermore, the mechanical heat conductive member is installed in the cold head apron by a flange with anti-freezing bellows or anti-freezing ripples.

The present invention also encompasses a superconducting magnet, with a superconducting coil thereof being provided in a cryogen vessel. The cryogen vessel is provided in an external vacuum chamber, and a thermal radiation shield is provided between the cryogen vessel and the external vacuum chamber, and the superconducting magnet is further provided with a precooling device as described above.

The present invention also encompasses a magnetic resonance imaging apparatus that includes a superconducting magnet as described above.

The present invention further encompasses a precooling method for a thermal radiation shield of a superconducting magnet, wherein a superconducting coil of the superconducting magnet is provided in a cryogen vessel, the cryogen vessel is provided in an external vacuum chamber, and a thermal radiation shield is provided between the cryogen vessel and the external vacuum chamber. The method according to the invention includes actively cooling the thermal radiation shield in the superconducting magnet down to a second temperature by a heat exchanger or a mechanical refrigerator before the second stage of precooling of the superconducting magnet, this second temperature being below the temperature of the thermal radiation shield after a first stage of precooling of the superconducting magnet.

According to an embodiment, the step of actively cooling down the thermal radiation shield using the heat exchanger includes making a heat conductor and a heat exchange tube of the heat exchanger into a mechanical heat conductive member in coordination with the structure of a cold head apron in the superconducting magnet, fixing the mechanical heat conductive member into the apron, and injecting continuously a cryogen into the heat exchange tube of the mechanical heat conductive member using cryogen supercharging equipment, so as to actively cool the thermal radiation shield down to the second temperature.

In this case, the cryogen may be liquid nitrogen, and the cryogen supercharging equipment may be a liquid nitrogen Dewar.

According to another embodiment, the step of actively cooling down the thermal radiation shield using the mechanical refrigerator includes making a heat conducting member of the mechanical refrigerator into a mechanical heat conductive member in coordination with the structure of a cold head apron in the superconducting magnet, fixing the mechanical heat conductive member into the apron, and starting the mechanical refrigerator to transfer cooling to the thermal radiation shield of the superconducting magnet via the mechanical heat conductive member and apron so as to actively cool the thermal radiation shield down to the second temperature.

In this case, the mechanical refrigerator may be a large refrigeration capacity single-stage G-M refrigerator.

It can be seen from the above embodiments that since the thermal radiation shield is actively cooled down to a second temperature before the second stage of precooling of the superconducting magnet in accordance with the present invention, and the second temperature is below the temperature of the thermal radiation shield after the first stage of precooling of the superconducting magnet, when the second stage of precooling is carried out on the superconducting magnet, the radiation heat of the thermal radiation shield that proceeds the cryogen vessel can be reduced, the consumption of cryogen (such as liquid helium) can be reduced during open-loop refrigeration, and the refrigeration speed can be increased during closed-loop refrigeration.

### BRIEF DESCRIPTION OF THE DRAWINGS

FIG. 1 is an exemplary structural chart of a precooling device for a thermal radiation shield of a superconducting magnet according to the embodiments of the present invention.

FIGS. 2a and 2b are structural schematic illustrations of a mechanical heat conductive member when a heat exchanger is used as a precooling device to precool the thermal radiation shield in a superconducting magnet in the embodiments of the present invention.

### DESCRIPTION OF THE PREFERRED EMBODIMENTS

In order to make the object, technical solutions and advantages of the present invention more apparent, the present invention will be further described in detail below by means of embodiments.

In the background art to which the aforementioned British patent application GB2433581A relates, first of all, a superconducting magnet is cooled down to a first temperature using liquid nitrogen, and at this time the thermal radiation shield is cooled from 300 K down to about 200 K, but when the superconducting magnet is cooled down to the operating temperature using liquid helium, the thermal radiation shield is still at the relatively high temperature of 200 K, i.e. it still has relatively high radiation heat onto the cryogen vessel. Therefore, when the thermal radiation shield is cooled from 200 K down to 50 K, it is necessary to evaporate plenty of liquid helium; however, the price of such liquid helium cryogen is very high, and it is very difficult to obtain a sufficient supply in some areas. At the same time, the consumption of liquid helium should be reduced as much as possible. The present utility model proposes another technical solution for reducing the consumption of cryogen.

In the embodiments of the present invention, it is considered that after a consumable cryogen is used to carry out a first stage of precooling of the superconducting magnet, the thermal radiation shield can only be cooled down to a first temperature, for example 200 K in the case of the thermal radiation shield of the superconducting magnet in MRI equipment, thus the use of other ways of cooling is considered before the second stage of precooling of the superconducting magnet, for example heat exchanger or mechanical refrigerator and so on; first of all, the thermal radiation shield is actively cooled down to a lower second temperature (the second temperature is below the first temperature), rather than passively cooling down the thermal radiation shield by the cryogen vessel, thus reducing the thermal radiation between the thermal radiation shield and the cryogen vessel, so that the consumption of cryogen (such as liquid helium) can be reduced when the cryogen is used to carry out the second stage of precooling of the superconducting magnet.

During its practical implementation, when the thermal radiation shield is cooled down to the second temperature using the heat exchanger or the mechanical refrigerator, the heat exchange member of the heat exchanger or the heat conducting member of the mechanical refrigerator can be in contact with the thermal radiation shield to cool down the thermal radiation shield. There can be various particular contact modes, for example, a cooling hole can be opened in the external vacuum chamber, and the heat exchange member of the heat exchanger or the heat conducting member of the mechanical refrigerator is in contact with said thermal radiation shield via said cooling hole. In addition, in order to make the best use of the structure of the currently available superconducting magnets without modification thereof, the cold head apron can be fully utilized, the cold head apron being used as the cooling hole during the mechanical refrigeration.

Accordingly, in the case where the thermal radiation shield is actively cooled down using the heat exchanger, it can include the following. The heat conductor and the heat exchange tube of the heat exchanger are made into a mechanical heat conductive member engaging with the structure of a cold head apron in the superconducting magnet, the mechanical heat conductive member is fixed into the apron during cooling, and cryogen is continuously injected into the heat exchange tube of the mechanical heat conductive member using cryogen supercharging equipment to cool the thermal radiation shield down to the second temperature.

In this case, the cryogen which is injected into the heat exchange tube can be liquid nitrogen, and can also be other cryogens. Accordingly, the cryogen supercharging equipment can be a liquid nitrogen Dewar, and can also be other supercharging equipment corresponding to the cryogen used.

The materials of the heat conductor and the heat exchange tube can be materials with very good thermal conductivity, such as red copper and so on, the heat conductor and the heat exchange tube can form an integral structure, and the heat exchange tube and the heat conductor can also be welded together using a tin soldering mode or other welding modes.

In this embodiment, when liquid nitrogen is used as the cryogen of the heat exchanger, as to the superconducting magnet in the MRI equipment, the temperature of the thermal radiation shield can be cooled down to about 100 K in this step, so that the radiation heat of the thermal radiation shield on the cryogen vessel can be greatly reduced.

In addition, in the case where the thermal radiation shield is cooled down to the second temperature using a mechanical refrigerator, it can include a heat conducting member of the mechanical refrigerator is made into a mechanical heat conductive member in coordination with the structure of a cold head apron of the superconducting magnet. The mechanical heat conductive member is fixed into the apron during cooling, and the mechanical refrigerator is started to transfer the cold to the thermal radiation shield via the mechanical heat conductive member and apron to cool the thermal radiation shield down to the second temperature. In this case, the mechanical refrigerator can be various refrigerators in the prior art, such as a large refrigeration capacity single-stage G-M refrigerator.

In this case, various implementations can be used to fix the mechanical heat conductive member of the heat exchanger or the mechanical refrigerator into the apron. For example, the mechanical heat conductive member can be installed in the apron using a flange with anti-freezing bellows or ripples. The mechanical heat conductive member can also be installed in the apron by an engaging structure of the mechanical heat conductive member and the apron.

The precooling method for a thermal radiation shield provided in the embodiments of the present invention can be carried out after the first stage of precooling of the superconducting magnet, and can also be carried out before the first stage of precooling of the superconducting magnet, and further can be carried out simultaneously with the first stage of precooling of the superconducting magnet. Alternatively, the precooling method for a thermal radiation shield provided in the embodiments of the present invention can be carried out independently, i.e. without considering the type of precooling carried out on the superconducting magnet, for example whether to carry out the first stage of precooling or not and so on.

The precooling method for a thermal radiation shield in the embodiments of the present invention is described in detail in the above, and the precooling device for a thermal radiation shield in the embodiments of the present invention will be described in detail hereinafter.

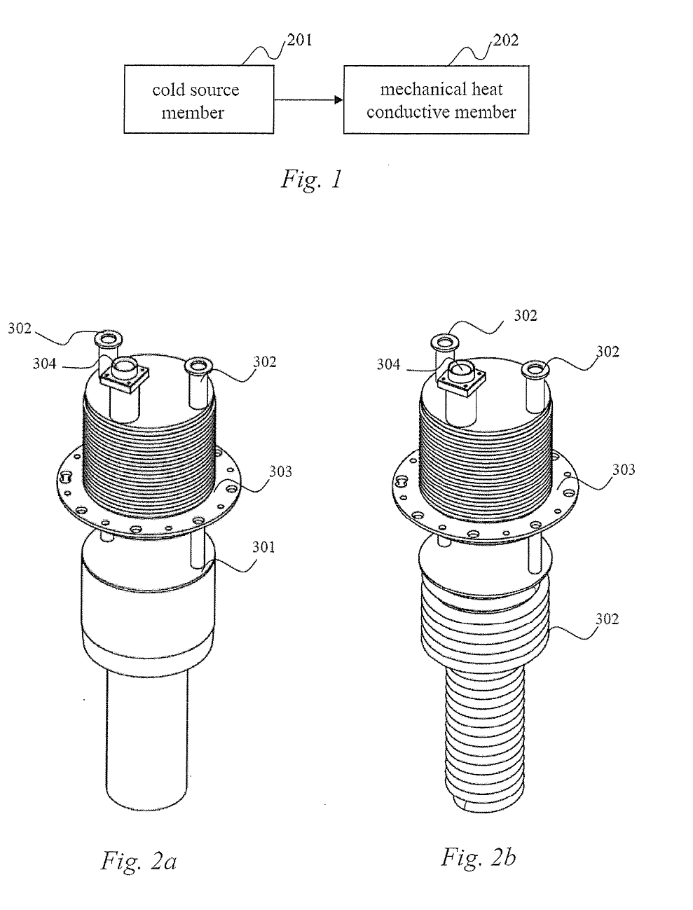

FIG. 1 is an exemplary structural chart of a precooling device for a thermal radiation shield of a superconducting magnet in the embodiments of the present invention. As shown in FIG. 1, the device has a cooling source member 201 for providing cooling to a mechanical heat conductive member and a mechanical heat conductive member 202 which is in contact with the thermal radiation shield and actively cools down the same.

In this case, the cold source member 201 is used for providing the cooling to the mechanical heat conductive member 202.

The mechanical heat conductive member 202 is used for having contact with the thermal radiation shield of the superconducting magnet, and actively cooling down the thermal radiation shield using the cooling provided by the cooling source member 201, for example, the thermal radiation shield is actively cooled down to the second temperature. The second temperature is below the temperature of the thermal radiation shield after the first stage of precooling of the superconducting magnet.

During its practical implementation, in accordance with the method disclosed in the embodiments of the present invention, the mechanical heat conductive member 202 in the device of this embodiment can also have a structure in engagement with the cold head apron of the superconducting magnet, and the thermal radiation shield is actively cooled down by fixing the mechanical heat conductive member 202 into the apron. In this case, various implementations can be used to fix the mechanical heat conductive member 202 into the apron. For example, the mechanical heat conductive member 202 can be installed in the apron by a flange with anti-freezing bellows or ripples. The mechanical heat conductive member can also be installed in the apron using a coordinated structure of the mechanical heat conductive member 202 and the apron.

In practical implementation, the precooling device in the embodiments of the present invention can be a heat exchanger. Accordingly, the cold source member 201 can be cryogen supercharging equipment, and the mechanical heat conductive member 202 can include the heat conductor and the heat exchange tube of the heat exchanger, wherein the heat conductor is in contact with the thermal radiation shield so as to actively cool down the thermal radiation shield, and the heat exchange tube is connected to the cooling source and is in contact with the heat conductor. The cryogen supercharging equipment is used for injecting the cryogen into the heat exchange tube of the mechanical heat conductive member 202. During its practical implementation, the materials of the heat conductor and the heat exchange tube can be materials with very good thermal conductivity, such as red copper, etc., and the heat conductor and the heat exchange tube can be a one-piece or integral structure, and the heat exchange tube and the heat conductor can also be bonded together by soldering or by welding techniques.

During practical implementation, the cryogen injected into the heat exchange tube can be liquid nitrogen, and can also be other cryogens. Accordingly, the cryogen supercharging equipment can be a liquid nitrogen Dewar, and can also be other supercharging equipment corresponding to the cryogen used.

In addition, the device in the embodiments of the present invention can also be a mechanical refrigerator. Accordingly, the cold source member 201 can be a refrigeration member of the mechanical refrigerator, and the mechanical heat conductive member 202 is the heat conducting member of the mechanical refrigerator. The heat conducting member is in contact with the thermal radiation shield, thereby actively cooling down the thermal radiation shield. In this case, the mechanical refrigerator can be any of various refrigerators in the prior art, such as a large refrigeration capacity single- stage G-M refrigerator.

FIGS. 2a and 2b schematically illustrate the structure of a mechanical heat conductive member when a heat exchanger is used as the precooling device for the thermal radiation shield of a superconducting magnet in an embodiment of the present invention. In this case, FIG. 2b is a view after the external structure of a local area in FIG. 2a has been removed. As shown in FIGS. 2a and 2b, the mechanical heat conductive member includes a heat conductor 301, a heat exchange tube 302, a flange 303 and a diagnosis port 304.

In this case, the heat conductor 301 and the heat exchange tube 302 are held together by tin soldering. The liquid nitrogen Dewar injects liquid nitrogen into the heat exchange tube 302 in the mechanical heat conductive member through the entrance of the heat exchange tube 302, and the nitrogen evaporated when the thermal radiation shield is cooled down flows out from the exit of the heat exchange tube 302.

The flange 303 has an anti-freezing bellows structure, for installing the mechanical heat conductive member into the cold head apron.

The diagnosis port 304 is used for viewing the current cooling temperature of the thermal radiation shield.

As to the superconducting magnet of the MRI equipment, the temperature of the thermal radiation shield can be reduced from 200 K to about 100 K using the mechanical heat conductive member shown in FIG. 2, or reduced from an atmospheric temperature of about 300 K to about 100 K, so that the radiation heat of the thermal radiation shield onto the cryogen vessel can be greatly reduced.

Although modifications and changes may be suggested by those skilled in the art, it is the intention of the inventor to embody within the patent warranted hereon all changes and modifications as reasonably and properly come within the scope of his contribution to the art.

1. A precooling device for a thermal radiation shield of a superconducting magnet, comprising:
a cooling source member;
a mechanical heat conductive member;
said cooling source member being configured to provide cooling to said mechanical heat conductive member; and
said mechanical heat conductive member being in contact with said thermal radiation shield, and configured to actively cool down the thermal radiation shield by utilizing the cooling provided by said cooling source member.

2. The device as claimed in claim 1, wherein said superconducting magnet comprises a cold head apron and wherein said mechanical heat conductive member comprises a structure configured to fix the mechanical heat conductive member into said apron.

3. The device as claimed in claim 2, wherein said device comprises device components that form a heat exchanger, and said mechanical heat conductive member comprises a heat conductor and a heat exchange tube of the heat exchanger, said heat conductor being in contact with said thermal radiation shield, and said heat exchange tube being connected to said cold source and in contact with said heat conductor.

4. The device as claimed in claim 2, wherein said device comprises components that form a mechanical refrigerator and said mechanical heat conductive member is a heat conducting member of the mechanical refrigerator.

5. The device as claimed in claim 2, wherein said mechanical heat conductive member is installed in the cold head apron by a flange with anti-freezing bellows.

6. A superconducting magnet, comprising:
a cryogen vessel containing a superconducting coil;
an external vacuum chamber surrounding said cryogen vessel;
a thermal radiation shield between the cryogen vessel and the external vacuum chamber; and
a precooling device for said thermal radiation shield, said precooling device comprising a cooling source member and a mechanical heat conductive member, said cooling source member being configured to provide cooling to said mechanical heat conductive member, and said mechanical heat conducting member being in contact with said thermal radiation shield and configured to actively cool down the thermal radiation shield by utilizing the cooling provided by said cooling source member.

7. A magnetic resonance imaging apparatus, comprising:
a magnetic resonance data acquisition unit comprising an examination volume configured to receive a subject therein;
a cryogen vessel containing a superconducting magnet surrounding said examination volume;
an external vacuum chamber surrounding said cryogen vessel;
a thermal radiation shield between the cryogen vessel and the external vacuum chamber; and
a precooling device for said thermal radiation shield, said precooling device comprising a cooling source member and a mechanical heat conductive member, said cooling source member being configured to provide cooling to said mechanical heat conductive member, and said mechanical heat conducting member being in contact with said thermal radiation shield and configured to actively cool down the thermal radiation shield by utilizing the cooling provided by said cooling source member.

8-9. (canceled)
